(19) United States
(12) Patent Application Publication
(10) Pub. No.: US 2007/0086555 A1
(43) Pub. Date: Apr. 19, 2007

(54) DLL circuit having two input standard clocks, clock signal generation circuit having the DLL circuit and clock signal generation method

(75) Inventor: Young-Kyun Cho, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/429,350

(22) Filed: May 5, 2006

(30) Foreign Application Priority Data
Oct. 14, 2005 (KR) 10-2005-0096808

(51) Int. Cl. H03D 3/24

(52) U.S. Cl. 375/376

(57) ABSTRACT

Provided is a delay locked loop circuit having two input standard clocks, a clock signal generation circuit including a delay locked loop circuit and a clock signal generation method. The delay locked loop circuit of the present invention includes a delay line unit, a phase comparator and a delay control unit. The delay line unit receives the first standard clock and generates an internal clock by delaying the first standard clock in response to a control signal. The phase comparator compares a phase difference between the first standard clock and a second standard clock with a phase difference between the first standard clock and the internal clock. The delay control unit generates a control signal to control a phase of the internal clock based on a comparison result of the phase comparator. According to the present invention, the clock signal having any phase shift may be simply generated by controlling the phase between an input and an output clock of the DLL based on the phase between two standard clocks and a layout size and a power consumption are greatly reduced.

### CROSS-REFERENCE TO RELATED PATENT APPLICATIONS

This application claims the priority of Korean Patent Application No. 10-2005-0096808, filed on 14 Oct. 2005, in the Korean Intellectual Property Office, the disclosure of which is incorporated herein in its entirety by reference.

### BACKGROUND OF THE INVENTION

1. Field of the Invention

The present invention relates to a clock signal generation circuit of semiconductor circuits, and more particularly, to a delay locked loop circuit in a digital mode (hereinafter indicated as DLL) receiving two standard clocks and generating an internal clock and a clock signal generation circuit comprising the DLL circuit.

2. Description of the Related Art

The DLL is a circuit for generating an internal clock synchronized to a standard clock signal. As an operational speed of a semiconductor memory device increases, the DLL is implemented inside of the semiconductor memory device for smooth data transfer between the semiconductor memory device and a memory controller. That is, the DLL generates the internal clock actuating a data output buffer by delaying an external clock supplied from the outside and the data output buffer outputs data coincident with a rising or a falling edge of the external clock in response to the internal clock.

Since the DLL does not have phase noise associated with a voltage controlled delay line, a smaller jitter and a superb frequency stability of the DLL compared to those of a phase locked loop (PLL) provides a faster locking time. On the other hand, the PLL has phase noise associated with the voltage controlled oscillator (VCO) due to its feedback nature. Therefore, the DLL is widely used in synchronization of clocks or forming various phases of clocks with low jitter noise and a stability.

A SDRAM (synchronous DRAM) device is synchronized to the clock signals and inputs or outputs data. In the case of SDRAM in a double data rate (DDR) mode, as data are read on both the rising edge and the falling edge of the clock signals, a speed of processing data is faster. For an interface of a double data rate, there is a 90° phase shifted clock signal, i.e., the clock signal having phase shifted as much as 1/(4T) required. Here, T is a period of the clock signal.

In a conventional technique, a delay line corresponding to 1/(4T) is implemented by inserting four times more delay lines to a master and using a mirror delay in a slave. That is, according to the conventional technique, the mater DLL requires the delay lines four times more than the slave delay lines to get the clock signals delayed as much as 1/(4T). Thereby, both layout size and power consumption have been increased.

### SUMMARY OF THE INVENTION

The present invention provides a delay locked loop (DLL) circuit requiring less layout size and less power consumption, and capable of supplying any phase shifted clock signal and a clock signal generation circuit comprising the same.

The present invention also provides a clock signal generation method of the clock signal generation circuit.

According to one aspect of the present invention, there is provided a delay locked loop circuit including a delay line unit, a phase comparator and a delay control unit. The delay line unit receives a first standard clock and generates an internal clock by delaying the first standard clock in response to a control signal. The phase comparator compares a phase difference between the first standard clock and a second standard clock with a phase difference between the first standard clock and the internal clock. The delay control unit generates the control signal for controlling a phase of the internal clock based on a comparison result of the phase comparator.

The phase comparator may include first through fourth latches. The first and second latches latch a predetermined input signal in response to the first standard clock. The third latch latches an output signal of the first latch in response to the internal clock and generates an increasing signal. The fourth latch latches an output signal of the second latch in response to the second standard clock and generates a decreasing signal. The logic unit compounds the increase signal and the decrease signal, and generates a reset signal to reset the first, the second, the third, and the fourth latch. In one embodiment, each of the first, the second, the third, and the fourth latches is implemented as a flip-flop. The delay control unit can comprise a FSM unit outputting a register value, which varies in response to the comparison result of the phase comparator, as the control signal.

In one embodiment, the delay line unit comprises: a delay line comprising multiple delay cells connected in series and generating multiple delay tap signals each having a different delay time by delaying the first standard clock; and a selector selecting one of the multiple delay tap signals and outputting the selected delay tap signal as the internal clock in response to the control signal.

In one embodiment, a phase difference between the first and the second standard clocks is substantially 90°.

According to another aspect of the present invention, there is provided a delay clocked loop (DLL) circuit including a master DLL circuit receiving the first and the second standard clock and generating the internal clock; and a slave circuit receiving the data output clock and generating a delay data output clock. The master DLL circuit includes the delay line unit, the phase comparator, and the delay control unit. The delay line unit receives the first standard clock and generates the internal clock by delaying the first standard clock received in response to the control signal. The phase comparator compares the phase difference between the first standard clock and the second standard clock with the phase difference between the first standard clock and the internal clock. The delay control unit generates the control signal to control a phase of the internal clock based on the comparison result of the phase comparator.

The slave circuit generates the delay data output clock by delaying the data output clock based on the control signal.

According to still another aspect of the present invention, there is provided a method of generating a clock signal. The method includes receiving the first standard clock and generating the internal clock by delaying the first standard clock in response to the control signal; comparing the phase difference between the first standard clock and the second standard clock with the phase difference between the first standard clock and the internal clock; and generating the control signal to control the phase of the internal clock based on a comparison result of the phase comparator.

It is desirable that the phase difference between the first standard clock and the second standard clock be substantially 90°.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. FIG. 1 is a block diagram of a clock signal generation circuit according to an embodiment of the present invention.

FIG. 2 is a block diagram of an embodiment of a PLL illustrated in FIG. 1.

FIG. 3 is a block diagram of an embodiment of a voltage controlled oscillator (VCO) illustrated in FIG. 2

FIG. 4 is a block diagram of a clock signal generation circuit according to another embodiment of the present invention.

FIG. 5 is a detailed block diagram of a voltage controlled delay line illustrated in FIG. 4.

FIG. 6 is a block diagram of a clock signal generation circuit according to still another embodiment of the present invention.

### DETAILED DESCRIPTION OF THE INVENTION

FIG. 1 is a block diagram of a clock signal generation circuit 100 according to an embodiment of the present invention. Refering to FIG. 1, the clock signal generation circuit 100 includes a PLL 200 and a DLL 300.

The DLL 300 includes a phase comparator 320, a FSM 360, and a delay line unit 380. The delay line unit 380 generates an internal clock ICLK by receiving a first standard clock I_out and delaying it for a predetermined time. A delay time of the delay line unit 380, i.e. the phase difference between a first standard clock I_out and the internal clock ICLK, is controlled by a control signal of the FSM 360.

The phase comparator 320 outputs a delay increase signal UP and a delay decrease signal DOWN by comparing a phase width between the first standard clock I_out and the internal clock ICLK with a phase width between the first standard clock I_out and the second standard clock Q_out. More specifically, the phase comparator 320 compares the phase difference between the first standard clock I_out and the internal clock ICLK with the phase difference between the first standard clock I_out and the second standard clock Q_out and outputs the delay increase signal UP or the delay decrease signal DOWN according to the comparison result.

The finite state machine FSM 360 responds to the increasing or the decreasing signal of the phase comparator and outputs a digital control signal to control the delay line unit 380. Therefore, the FSM 360 may be referred to as the delay control unit generating the control signals DCON to control a phase of the internal clock ICLK according to the comparison result of the phase comparator 320.

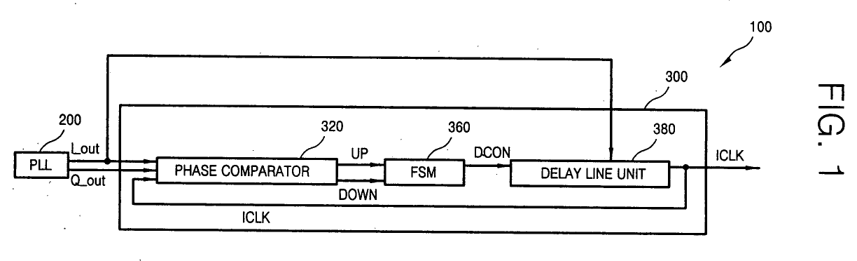

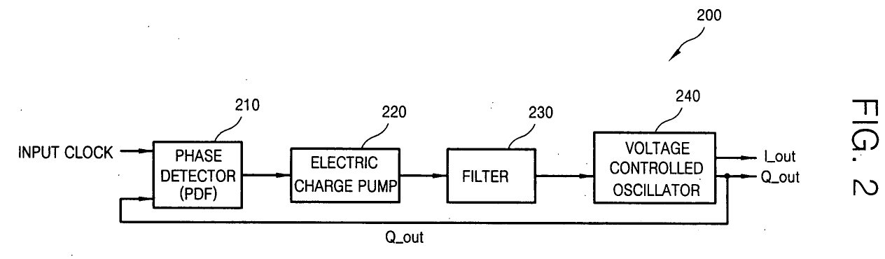

FIG. 2 is a block diagram of an embodiment of the PLL 200 illustrated in FIG. 1. The PLL 200 includes a phase frequency detector PFD 210, an electric charge pump 220, a filter 230, and the voltage controlled oscillator (VCO) 240. The phase frequency detector 210 has a function of a frequency detector as well as a phase detector. The phase frequency detector 210 receives a feedback signal Q_out output from the input clock and the VCO and outputs a comparative signal corresponding to a phase difference and a frequency difference between both signals. The electric charge pump 220 outputs a control voltage in response to the comparative signal of the phase frequency detector 210. The filter 230 filters a high frequency component of the control voltage output from the phase frequency detector 210 as a low-pass filter. The VCO 240 generates the first and the second standard clock I_out and Q_out each having a different phase with the control voltage filtered by the filter 230 input.

It is desirable that the phase difference between the first and the second standard clock I_out and Q_out is 90°. However, there may be any phase differences between the first and the second standard clock I_out and Q_out. The second standard clock Q_out as a feedback clock Q_out is fed back to the phase frequency detector 210. However, the first standard clock I_out may be fed back to the phase frequency detector 210 and a divided clock of the first standard clock I-out or the second standard clock Q_out may be feedback to the phase frequency detector 210.

The first and the second standard clock I_out and Q_out are input to the phase comparator 320 of the DLL 300, the first standard clock I_out is also input to the delay line unit 380. Refering to FIG. 2, the PLL 200 is used for generating the two standard clock signals I_out and Q_out having different phase. However, the present invention is not restricted to the PLL 200.

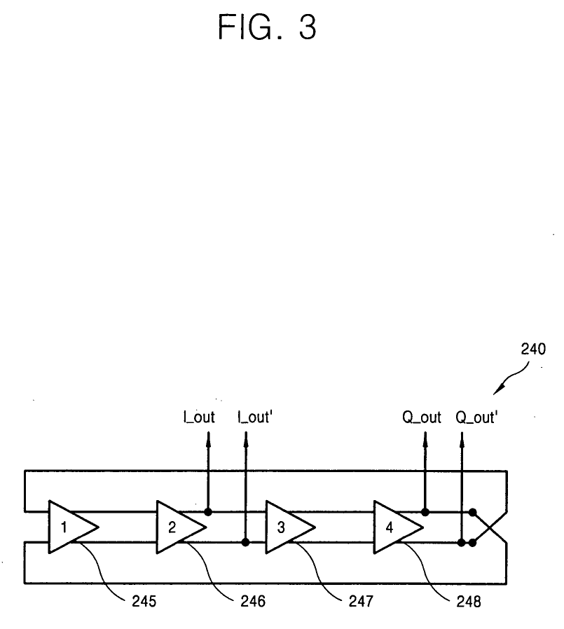

FIG. 3 is a block diagram of an embodiment of the VCO 240 illustrated in FIG. 2. Referring to FIG. 3, the VCO 240 includes four stage differential delay cells 245, 246, 247 and 248. The four stage differential cells 245, 246, 247 and 248 are referred to herein as a first, a second, a third, and a fourth differential delay cell.

By connecting an output of the last stage (the fourth stage) to an input of the first stage, a delay cell stage may be implemented in an even number by connecting the stages as illustrated in FIG. 3. That is, an output terminal of the fourth differential delay cell 248 is contrarily connected to an input terminal of the first differential delay cell 245.

The first standard clock pair I_out and I_out′ are output from a middle stage of the VCO 240, i.e. the second differential delay cell 246, and the second standard clock pair Q_out and Q_out′ are output from the last stage, i.e. the fourth differential delay cell 248.

Since the number of the differential delay cells which form the VCO 240 is even, there is a phase difference of 90° between the middle stage output and the last stage output of the VCO 240. Therefore, there is a phase difference of 90° between the first standard clock I_out and the second standard clock Q_out and there is also a 90° phase difference between I_out′ and Q_out′. I_out and Q_out are used as two standard clocks input to the DLL 300 in the embodiment, but I_out′ and Q_out′ may be also used as two standard clocks input to the DLL 300.

To generate two standard clocks having any phase difference except 90°, a number of the delay cell stages of the VCO 240 may be changed and an output point of the standard clock may be changed.

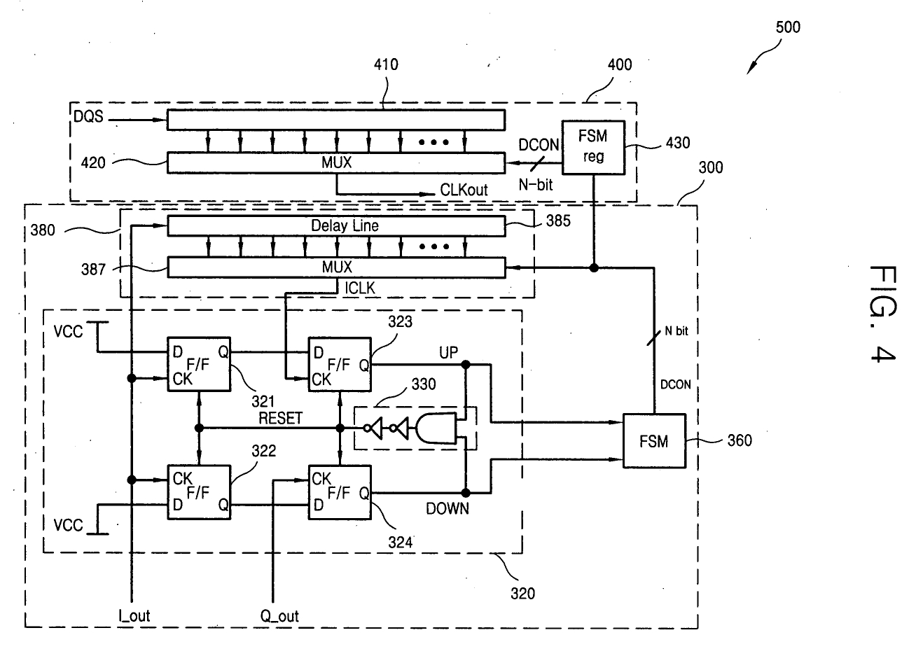

FIG. 4 is a block diagram of a clock signal generation circuit 500 according to another embodiment of the present invention. Referring to FIG. 4, the clock signal generation circuit 500 includes the master DLL 300 and the slave circuit 400. The master DLL 300 is referred to as the master DLL circuit for the purpose of this description, but the structure is the same as the DLL 300 illustrated in FIG. 1. FIG. 4 illustrates only a detailed formation of structural elements 320 and 360 of the DLL 300.

Referring to FIG. 4, each structure and each operation is described in detail as follows. The phase comparator 320 includes a plurality of latches 321, 322, 323, 324, and a logic unit 330. Each of the latches 321, 322, 323, 324 can be implemented as a flip-flop circuit. The latches 321, 322, 323, 324 are referred to as a first, a second, a third, and a fourth flip-flop circuit. The first standard clock I_out is input to a clock terminal CK of the first and the second flip-flop circuits 321, 322. and a predetermined power supply voltage VCC is inputted to the input terminal ICLK of the first and the second flip-flop circuits 321, 322. The internal clock ICLK is inputted to the clock terminal CK of the third flip-flop 323 and the output signal Q of the first flip-flop 321 is inputted to the input terminal D of the third flip-flop 323. The second standard clock Q_out is inputted to the clock terminal CK of the fourth flip-flop 324 and the output signal Q of the second flip-flop 322 is inputted to the input terminal D of the fourth flip-flop 324.

The first and the second flip-flops 321, 322 output a high level signal in response to the first standard clock I_out. The third flip-flop 323 outputs the increase signal UP by latching the output signal of the first flip-flop 321 in response to the internal clock ICLK. The fourth flip-flop 324 outputs the decrease signal DOWN by latching the output signal of the second flip-flop 322 in response to the second standard clock Q_out.

Therefore, when the phase of the internal clock ICLK is faster than that of the second standard clock Q_out, the increase signal UP is activated to a high level; when the phase of the internal clock ICLK is slower than that of the second standard clock Q_out, the decrease signal DOWN is activated to a high level.

The logic unit 330 includes two inverters and an AND gate. The AND gate generates a reset signal RESET through two inverters after executing a logical AND operation of the increasing signal UP and the decreasing signal DOWN. Hence, when both the increasing signal UP and the decreasing signal DOWN reach a high level, the reset signal RESET also reaches a high level and the first through the fourth flip-flops 321, 322, 323, 324 are reset to a low level.

The phase comparator 320 compares the phase difference between the first and the second standard clock I_out and Q_out (Ta, referred to as a first phase difference) with the phase difference between the first standard clock I_out and the internal clock ICLK(Tb, referred to as a second phase difference), generates the increase signal UP or the decrease signal DOWN according to the comparison result.

The phase of the internal clock ICLK is controlled to be equal to the phase of the second standard clock Q_out by the increase signal UP and the decrease signal DOWN. Therefore, the digital loop is formed and locked for making the second phase difference Tb and the first phase difference Ta equal.

The finite state machine 360 has a different internal register value corresponding to the increasing signal UP or the decreasing signal DOWN of the phase comparator. The internal register value is output as a digital control signal DCON of N bits and it is inputted to the delay line unit 380. The internal registal value of the FSM 360 is delivered to the FSM 430, a replica of the slave circuit 400 described in the following.

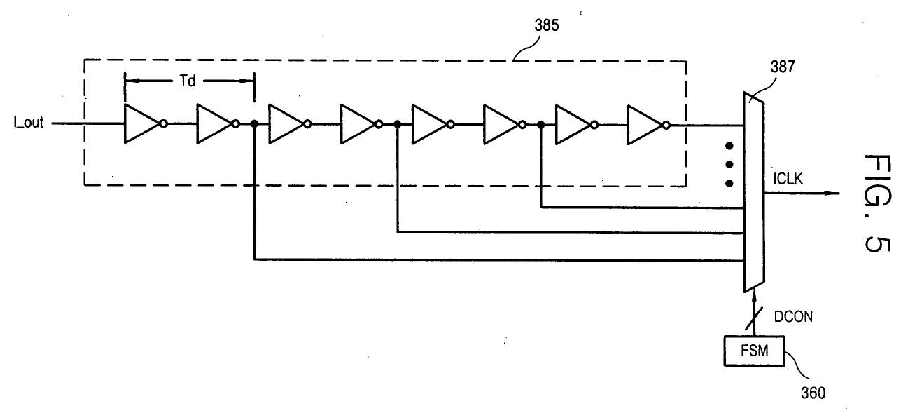

The delay line unit 380 includes the delay line 385 and a multiplexer 387. FIG. 5 is a block diagram of the delay line unit 380 in detail.

Referring to FIG. 5, the delay line 385 includes a plurality of delay cells connected in series. The delay cells may be implemented as the inverter illustrated in FIG. 5. The delay line 385 outputs a plurality of delay tap signals by delaying the first standard clock I_out and outputting the delay tap signal of each delay cell. A delay interval between the delay tap signals is determined according to a delay time Td of one delay cell.

The multiflexer 387 chooses one of the delay tap signals output from the delay line 385 in response to the digital control signal DCON and outputs it as the internal clock ICLK. Thus, a tap location of the delay line 385 is decided by the digital control signal DCON. That is, it is decided by the digital control signal DCON which signal among a plurality of the delay tap signals is chosen as the internal clock ICLK.

Referring to FIG. 4 again, the slave circuit 400 includes a DQS delay line 410, the multiflexer 420 and a replica of FSM reg 430.

It is desirable that the DQS delay line 410 be a replica of the delay line 385. The DQS delay line 410 outputs a plurality of the delay tap signals by delaying a data output clock DQS. The multiflexer 420 outputs the delay data output clock CLKout by choosing one of the plural delay tap signals output from the DQS delay line 410 in response to an output signal of the replica FSM reg 430. Here, since the internal register value of the FSM 360 is delivered to the replica FSM reg 430 as it is, the output signal of the replica FSM reg 430 is the same as the digital control signal DCON which is an output signal of the FSM 360. The phase difference between the data output clock DQS and the delay data output clock CLKout is equal to the phase difference between the first standard clock I_out and the internal clock ICLK.

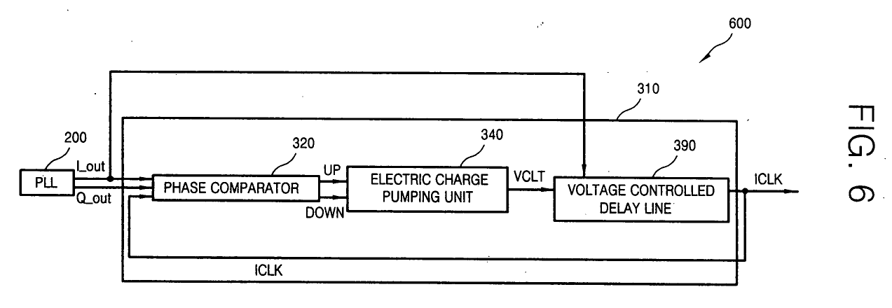

FIG. 6 illustrates a signal generation circuit 600 according to still another embodiment of the present invention. Referring to FIG. 6, the clock signal generation circuit 600 includes the PLL 200 and the DLL 310. The DLL 310 includes the phase comparator 320, the electric charge pumping unit 340 and the voltage controlled delay line 390.

The voltage controlled delay line unit 390 outputs the internal clock ICLK by receiving the first standard clock I_out and delaying it for a predetermined time. A delay time of the voltage controlled delay line unit 390, that is, the phase difference between the first standard clock I_out and the internal clock ICLK is adjusted by a voltage level of the delay control signal VCLT supplied by the electric charge pumping unit 340.

The phase comparator 320 outputs the delay increasing signal UP and the delay decreasing signal DOWN by comparing the phase difference between the first standard clock I_out and the internal clock ICLK with the phase difference between the first and the second standard clock I_out and Q_out. More specifically, the phase comparator 320 compares the phase difference between the first standard clock I_out and the internal clock ICLK and outputs the delay increasing signal UP or the delay decreasing signal DOWN according to the comparison result.

The electric charge pumping unit 340 adjusts the voltage level of the delay control signal VCLT based on the comparison result of the phase comparator 320. In detail, the electric charge pumping unit 340 outputs the delay control signal VCLT which level is changed according to the delay increasing signal UP or the delay decreasing signal DOWN by pumping an electric charge in response to the delay increasing signal UP or the delay decreasing signal DOWN output from the phase comparator 320.

While the DLL 300 illustrated in FIGS. 1 and 4 is in a digital mode, the DLL 310 illustrated in FIG. 6 is in an analog mode.

The clock signal generation circuit 600, like the clock signal generation circuit 500 illustrated in FIG. 4, may further include the slave circuit (not shown) for outputting data. In this case, the slave circuit includes a replica of the voltage controlled delay line of the voltage controlled delay line 390 and the replica of the voltage controlled delay line has the delay time preferably controlled by the voltage level of the delay control signal VCLT.

According to the present invention, the clock signal having any phase shift may be readily generated by adjusting the phase between the input and the output clock of the DLL based on the phase between two standard clocks. Also, according to the present invention, since the master delay line does not need to be bigger than the slave delay line, a layout size and a power consumption are greatly reduced compared to a conventional method.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A delay locked loop circuit comprising:
a delay line unit receiving a first standard clock and generating an internal clock by delaying the first standard clock in response to a control signal;
a phase comparator comparing a phase difference between the first standard clock and a second standard clock with a phase difference between the first standard clock and the internal clock; and
a delay control unit generating the control signal for controlling a phase of the internal clock based on a comparison result of the phase comparator.

2. The delay locked loop circuit as claimed in claim 1, wherein the phase comparator comprises:
a first and a second latch latching a predetermined input signal in response to the first standard clock;
a third latch generating an increase signal by latching an output signal of the first latch in response to the internal clock;
a fourth latch generating a decrease signal by latching an output signal of the second latch in response to the second standard clock; and
a logic unit generating a reset signal to reset the first, the second, the third and the fourth latch by compounding the increase signal and the decrease signal.

3. The delay locked loop circuit as claimed in claim 2, wherein each of the first, the second, the third, and the fourth latches is implemented as a flip-flop.

4. The delay locked loop circuit of claim 2, wherein the delay control unit comprises a FSM unit outputting a register value, which varies in response to the comparison result of the phase comparator, as the control signal.

5. The delay locked loop circuit of claim 1, wherein the delay line unit comprises:
a delay line comprising multiple delay cells connected in series and generating multiple delay tap signals each having a different delay time by delaying the first standard clock; and
a selector selecting one of the multiple delay tap signals and outputting the selected delay tap signal as the internal clock in response to the control signal.

6. The delay locked loop circuit of claim 1, wherein a phase difference between the first and the second standard clock is substantially 90°.

7. A clock signal generation circuit comprising:
a master DLL circuit receiving a first and a second standard clock and generating an internal clock; and
a slave circuit receiving a data output clock and generating delay data output clocks,
wherein the master DLL circuit comprises:
a delay line unit receiving the first standard clock and generating the internal clock by delaying the first standard clock in response to a control signal;
a phase comparator comparing the phase difference between the first and the second standard clock with the phase difference between the first standard clock and the internal clock; and
a delay control unit generating the control signal for controlling a phase of the internal clock based on the comparison result of the phase comparator,
wherein the slave circuit generates the delay data output clock by delaying the data output clock based on the control signal.

8. The clock signal generation circuit of claim 7, wherein the delay line unit comprises:
a delay line including multiple delay cells connected in series and generating a plurality of first delay tap signals each having a different delay time; and
a first selector selecting one of the multiple first delay tap signals and outputting it as the internal clock in response to the control signal,
wherein the slave circuit comprises:
a replica of the delay line substantially the same as the delay line and generating a plurality of second delay tap signals by receiving the data output clock; and
a second selector selecting one of the multiple second delay tap signals and outputting it as the delay data output clock in response to the control signal

9. The clock signal generation circuit of claim 7, wherein the phase comparator comprises:
a first and a second latch latching a predetermined input signal in response to the first standard clock;
a third latch latching an output signal of the first latch in response to the internal clock and generating an increase signal;
a fourth latch latching an output signal of the second latch in response to the second standard clock and generating a decrease signal; and
a logic unit generating the reset signal to reset the first, the second, the third, and the fourth latch by compounding the increasing signal and the decreasing signal,
wherein the delay control unit generates the control signal in response to the increasing signal and the decreasing signal.

10. The clock signal generation circuit of claim 7, further comprising a PLL circuit generating the first and the second standard clock each having a different phase.

11. The clock signal generation circuit of claim 10, wherein the PLL circuit comprises:
a voltage controlled oscillator including multiple differential delay cells connected in series,
wherein the first standard clock is output from one of the multiple differential delay cells and the second standard clock is output from another of the multiple differential delay cells.

12. The clock signal generation circuit of claim 7, wherein the delay control unit comprises an electric charge pumping unit varying a voltage level of the control signal by pumping an electric charge in response to the comparison result of the phase comparator,
and wherein the delay line unit comprises a voltage controlled delay line having delay time varied in response to the voltage level of the control signal.

13. A clock signal generation method comprising:
receiving a first standard clock and generating an internal clock by delaying the first standard clock in response to a control signal;
comparing a phase difference between the first and a second standard clock with a phase difference between the first standard clock and the internal clock; and
generating the control signal for controlling a phase of the internal clock based on a comparison result of the phase comparator.

14. The method of claim 13, further comprising receiving data output clocks and generating delay data output clocks by delaying the data output clocks in response to the control signal.

15. The method of claim 13, wherein the phase difference between the first and the second standard clock is substantially 90°.
